(19) United States
(12) Patent Application Publication
(10) Pub. No.: US 2016/0071940 A1
(43) Pub. Date: Mar. 10, 2016

(54) SEMICONDUCTOR DEVICE

(71) Applicant: Kabushiki Kaisha Toshiba, Tokyo (JP)

(72) Inventor: Hideki Okumura, Nonoichi Ishikawa (JP)

(21) Appl. No.: 14/639,471

(22) Filed: Mar. 5, 2015

(30) Foreign Application Priority Data
Sep. 8, 2014 (JP) 2014-182332

(51) Int. Cl. H01L 29/423; H01L 29/49; H01L 29/78

(52) U.S. Cl. CPC H01L 29/4236; H01L 29/7827; H01L 29/4916

(57) ABSTRACT

According to an embodiment, a semiconductor device includes a first semiconductor layer of a first conductivity type, a first electrode over the first semiconductor layer, second and third electrodes extending in the first semiconductor layer in a direction from the first electrode to the first semiconductor layer, a second semiconductor layer of a second conductivity type on the first semiconductor layer. The device further includes third semiconductor layers of the second conductivity type between the first semiconductor layer and each of the second electrode and the third electrode, first insulating films between one of the third semiconductor layers and the second electrode and between the other of the third semiconductor layers and the third electrode, a fourth semiconductor layer of the first conductivity type on the second semiconductor layer, and a fourth electrode extending through the fourth semiconductor layer and the second semiconductor layer to the first semiconductor layer.

### CROSS-REFERENCE TO RELATED APPLICATIONS

This application is based upon and claims the benefit of priority from Japanese Patent Application No. 2014-182332, filed on Sep. 8, 2014; the entire contents of which are incorporated herein by reference.

### FIELD

Embodiments are related generally to a semiconductor device.

### BACKGROUND

Power semiconductor devices such as power MOS (metal oxide semiconductor) transistors require high breakdown voltage and low on-resistance. For instance, in a MOS transistor of the trench gate type, the impurity concentration of the drift layer is increased to reduce the on-resistance. In such a case, a field plate electrode of the source potential is preferably placed below the gate electrode in the trench gate to promote depletion of the drift layer. Thus, higher breakdown voltage is simultaneously achieved with the low on-resistance.

In order to achieve a semiconductor device having a higher breakdown voltage, it may be desirable to make the drift layer thicker, and to form the deeper gate trench. Thus, increasing the share of the drain voltage applied to the field insulating film between the field plate electrode and the drift layer may be unavoidable in such a case. As a result, it is necessary to increase a thickness of the field insulating film to achieve the higher breakdown voltage. The thicker field insulating film, however, has disadvantage such as wafer warpage, which increases difficulty in the manufacturing process of the semiconductor device.

### BRIEF DESCRIPTION OF THE DRAWINGS

FIGS. 1A and 1B are schematic cross-sectional views showing a semiconductor device according to an embodiment;

FIGS. 2A to 6B are schematic cross-sectional views showing a manufacturing process of the semiconductor device according to the embodiment; and

FIGS. 7A and 7B are schematic cross-sectional views showing a semiconductor device according to a variation of the embodiment.

### DETAILED DESCRIPTION

According to an embodiment, a semiconductor device includes a first semiconductor layer of a first conductivity type, a first electrode over the first semiconductor layer, a second electrode extending in a first direction from the first electrode to the first semiconductor layer, the second electrode having a first end in the first semiconductor layer and a second end in contact with the first electrode, a third electrode extending in the first direction, the third electrode having a first end in the first semiconductor layer and a second end in contact with the first electrode, a second semiconductor layer of a second conductivity type on the first semiconductor layer between the second electrode and the third electrode. The device further includes third semiconductor layers of the second conductivity type between the first semiconductor layer and the second electrode and between the first semiconductor layer and the third electrode, first insulating films between one of the third semiconductor layers and the second electrode and between the other of the third semiconductor layers and the third electrode, a fourth semiconductor layer of the first conductivity type on the second semiconductor layer, the fourth semiconductor layer being electrically connected to the first electrode, and a fourth electrode extending through the fourth semiconductor layer and the second semiconductor layer to the first semiconductor layer via a second insulating film.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

The following embodiments are described assuming that the first conductivity type is n-type and the second conductivity type is p-type. However, the embodiments are not limited thereto. The first conductivity type may be p-type, and the second conductivity type may be n-type.

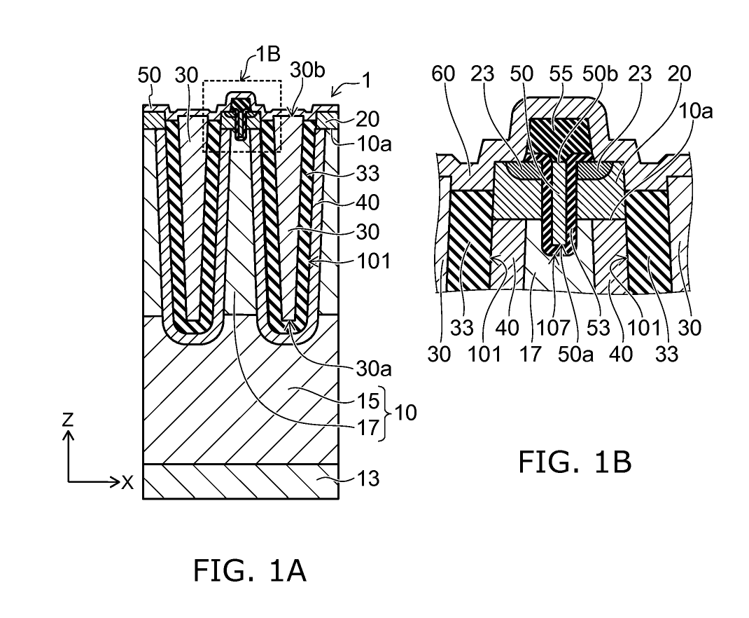

FIGS. 1A and 1B are schematic cross-sectional views illustrating a semiconductor device 1 according to an embodiment. The semiconductor device 1 is, for example, a power MOS transistor. FIG. 1A shows the cross-sectional structure of a unit cell of the semiconductor device 1. FIG. 1B is an enlarged view of the region 1B shown in FIG. 1A.

The semiconductor device 1 includes an n-type first semiconductor layer (hereinafter, drift layer 10) and a p-type second semiconductor layer (hereinafter, base layer 20) provided on the drift layer 10. The drift layer 10 is provided on a drain layer 13, for example. The drain layer 13 is a layer having a higher n-type impurity concentration than the drift layer 10. The drain layer 13 may be an n-type semiconductor layer or an n-type semiconductor substrate, for example.

As shown in FIGS. 1A and 1B, the drift layer 10 includes a first layer 15 and a second layer 17. The second layer 17 is provided on the first layer 15. The second layer 17 has an n-type impurity concentration higher than an n-type impurity concentration of the first layer 15. The second layer 17 has an n-type impurity concentration lower than an n-type impurity concentration of the drain layer 13.

The semiconductor device 1 includes a first electrode (herein after, a source electrode 60), a second electrode and a third electrode (hereinafter, field plate electrodes 30). The semiconductor device 1 further includes a fourth electrode (hereinafter, a gate electrode 50) between the second electrode and the third electrode.

The semiconductor device 1 includes a plurality of field plate electrodes 30. The field plate electrodes 30 are arranged in the X-direction along the boundary 10a of the drift layer 10 and the base layer 20, for example.

The field plate electrode 30 extends in a second direction opposite to the Z-direction through the base layer 20 to the drift layer 10. The first end 30a thereof is located in the drift layer 10. The second end 30b thereof is located on the base layer 20 side. The first end 30a is preferably located in the first layer 15.

The semiconductor device 1 includes a p-type semiconductor layer (hereinafter, p-type layer 40) and a first insulating film (hereinafter, a field plate insulating film 33). The p-type layer 40 is provided between the drift layer 10 and each of the field plate electrodes 30. The field plate insulating film 33 is provided between each of the field plate electrodes 30 and the p-type layer 40. The p-type layer 40 is provided to be connected to the base layer 20.

For instance, the field plate electrode 30 is provided via the field plate insulating film 33 in a first trench (hereinafter, trench 101) extending through the base layer 20 to the drift layer 10. The p-type layer 40 is provided along the field plate insulating film 33.

The semiconductor device 1 further includes the gate electrode 50 between the adjacent field plate electrodes 30. Furthermore, the semiconductor device 1 includes an n-type fourth semiconductor layer (hereinafter, a source layer 23) selectively provided on the base layer 20 between the adjacent field plate electrodes 30. The gate electrode 50 faces the drift layer 10, the base layer 20, and the source layer 23 via a second insulating film (i.e. a gate insulating film 53).

For example, one end 50a of the gate electrode 50 is located at a level in the drift layer 10, which is shallower than the first end 30a and deeper than the boundary 10a of the drift layer 10 and the base layer 20. The other end 50b of the gate electrode 50 is located on the base layer 20 side of the boundary 10a.

In other words, as shown in FIG. 1B, the gate electrode 50 is provided via the gate insulating film 53 inside a second trench (hereinafter, trench 107) extending through the base layer 20 to the drift layer 10. The trench 107 is provided between the two adjacent trenches 101 with a depth so that the end thereof reaches the second layer 17 through the base layer 20. That is, the trench 107 is provided with a depth shallower than a depth of the trench 101.

The source layer 23 is selectively provided on a portion of the base layer 20 that is located on the gate electrode 50 side. The gate electrode 50 faces the second layer 17, the base layer 20, and the source layer 23 via the gate insulating film 53 that is provided on an inner surface of the trench 107.

Furthermore, the semiconductor device 1 includes the source electrode 60 that is provided over the base layer 20, the source layer 23, the field plate electrode 30, and the gate electrode 50. The source electrode 60 is electrically connected to the base layer 20, the source layer 23, and the field plate electrodes 30. An interlayer insulating film 55 is provided between the gate electrode 50 and the source electrode 60. Thus, the gate electrode 50 and the source electrode 60 are electrically insulated from each other. The source electrode 60 is in contact with the second end 30b of the field plate electrode 30.

The semiconductor device 1 is configured so that the total amount of p-type impurities contained in the p-type layer 40 is equal to the total amount of n-type impurities contained in the drift layer 10 and the p-type layer 40. That is, charge balance is preferably attained to deplete the whole drift layer 10 and the p-type layer 40 when the p-n junction between the base layer 20 and the drift layer 10 and between the p-type layer 40 and the drift layer is reverse biased.

Here, “equal” is not limited to the case where the amount of impurity is equal in a strict sense, but allows a difference due to the inaccuracy of the doping amount of impurities in the manufacturing process. That is, it is allowable that the total amount of p-type impurities contained in the p-type layer 40 is nearly equal to the total amount of n-type impurities contained in the drift layer 10 and the p-type layer 40.

In this embodiment, the field plate electrode 30 that has the same potential with the source electrode 60 is provided inside the trench 101 surrounded by the p-type layer 40. This promotes the depletion of the p-type layer 40. Thus, it is possible to make the total amount of p-type impurities contained in the p-type layer 40 larger than the total amount of n-type impurities contained in the drift layer 10 and the p-type layer 40.

Furthermore, the p-type layer 40 that is interposed between the field plate insulating film 33 and the drift layer 10 makes it possible to reduce the voltage applied to the field plate insulating film 33. That is, a proportion of the voltage applied to the field plate insulating film 33 can be reduced in the drain voltage applied between the field plate electrode 30 and the drain layer 13. As a result, it becomes possible to reduce the thickness of the field plate insulating film 33.

For achieving the semiconductor device 1 that has the higher breakdown voltage and lower on-resistance, it is preferable to make the second layer 17 thicker in the Z-direction, and to make the trench 101 deeper. Then, the field plate insulating film 33 tends to be thicker as the depth of the trench 101 becomes deeper. As a result, the wafer warpage becomes larger as increasing the thickness of the field plate insulating film 33, thereby making the manufacturing process more difficult. In contrast, it is possible in this embodiment to mitigate the wafer warpage by reducing the thickness of the field plate insulating film 33 compared with the case without the p-type layer 40. Suppressing the wafer warpage may reduce the difficulty for achieving the higher breakdown voltage and lower on-resistance in the manufacturing process of the semiconductor device 1.

The p-type layer 40 is formed to extend along the field plate insulating film 33, and connected to the base layer 20, and thus, the p-type layer 40 may act as a pathway for removing holes generated in the drift layer 10 by impact ionization in the avalanche process. Thus, it may also become possible to increase the avalanche resistance of the semiconductor device 1.

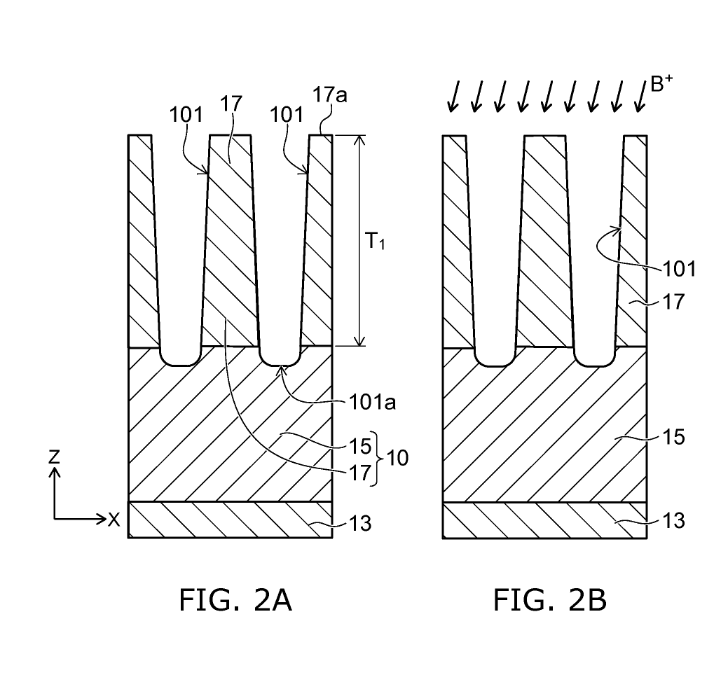

Next, a method for manufacturing the semiconductor device 1 according to the embodiment is described with reference to FIGS. 2A to 6B. FIGS. 2A to 6B are schematic sectional views illustrating the manufacturing process of the semiconductor device according to the embodiment.

As shown in FIG. 2A, a wafer is prepared, which includes a drift layer 10 formed on a drain layer 13. The drain layer 13 may be an n-type silicon wafer, or an n-type silicon layer epitaxially grown on the n-type silicon wafer. The drift layer 10 is an n-type silicon layer, for example. The drift layer 10 includes a first layer 15 epitaxially grown on the drain layer 13, and a second layer 17. The second layer 17 is provided so that the n-type impurity concentration thereof is higher than the n-type impurity concentration of the first layer 15.

Next, a trench 101 is formed to extend through the second layer 17 to the first layer 15. The trench 101 is formed by the anisotropic RIE (reactive ion etching) technique, for example. The trench 101 is formed deeper in the Z-direction than the thickness T₁ of the second layer 17. T₁ is 10-20 micrometers (μm), for example.

Next, p-type impurity such as boron (B) is ion-implanted into the inner surface of the trench 101 as shown in FIG. 2B. Boron ions (B⁺) are implanted in an oblique direction at several degrees against the Z-direction perpendicular to the wafer so as to be implanted into the sidewall of the trench 101. The dose amount of boron is adjusted to be equal to the total amount of n-type impurity contained in the drift layer 10.

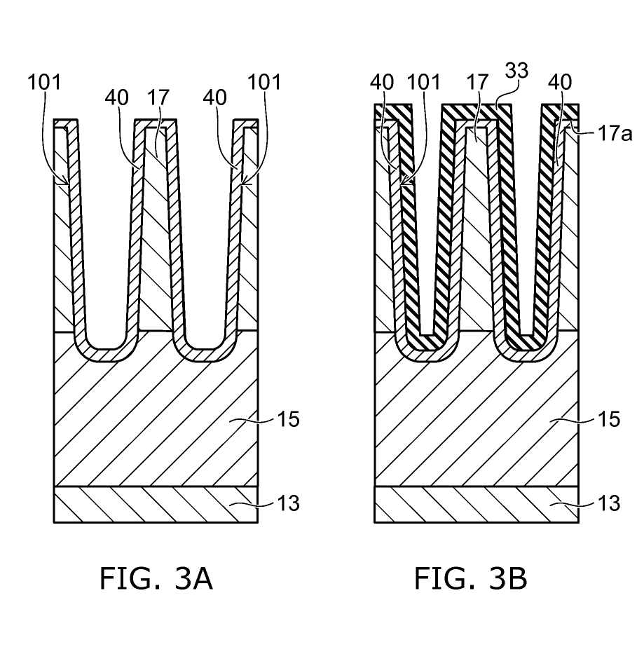

Next, as shown in FIG. 3A, the wafer is annealed to activate the ion-implanted boron. Thus, a p-type layer 40 is formed at the inner surface of the trench 101.

The method for forming the p-type layer 40 is not limited to the ion implantation. For instance, a p-type silicon layer may be epitaxially grown on the inner surface of the trench 101. Also in this case, the p-type layer 40 is formed by controlling the p-type impurity concentration so that the total amount of p-type impurities contained in the p-type silicon layer is balanced with the total amount of n-type impurities contained in the drift layer 10.

As shown in FIG. 3B, a field plate insulating film 33 is formed to cover the inner surface of the trench 101. The field plate insulating film 33 is a silicon oxide film, for example. The field plate insulating film 33 is formed using CVD (chemical vapor deposition) technique. The field plate insulating film 33 is formed on the entire surface of the wafer. The field plate insulating film 33 covers the upper surface 17a of the second layer 17 on which the p-type layer 40 is formed.

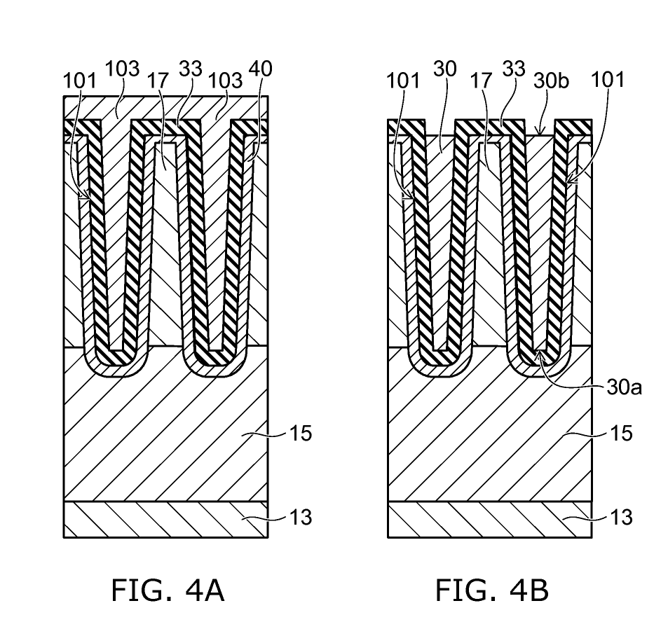

As shown in FIG. 4A, a conductive film 103 is deposited on the entire surface of the wafer, embedding the trench 101. The conductive film 103 is made of conductive polycrystalline silicon, for example. The conductive film 103 is formed using CVD technique.

As shown in FIG. 4B, the conductive film 103 is etched back, leaving a field plate electrode 30 in the trench 101. The first end 30a of the field plate electrode 30 is located in the first layer 15. The second end 30b of the field plate electrode 30 is exposed on the opening side of the trench 101.

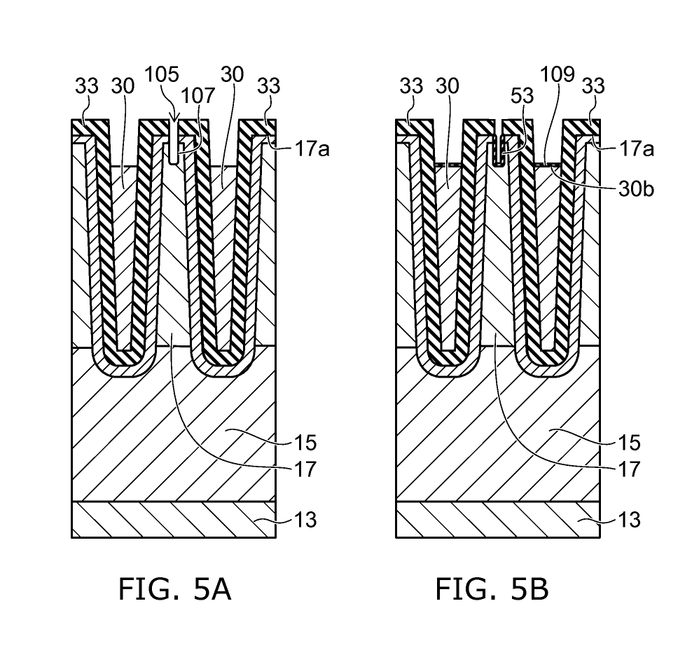

As shown in FIG. 5A, a trench 107 is formed. For instance, an opening 105 is formed in a portion of the field plate insulating film 33 on the second layer 17. Then, the second layer 17 is etched to form the trench 107 using the field plate insulating film 33 as an etching mask.

As shown in FIG. 5B, the inner surface of the trench 107 is thermally oxidized to form a gate insulating film 53. At this time, the second end 30b of the field plate electrode 30 is also oxidized. Thus, for instance, a silicon oxide film 109 is formed on the field plate electrode 30.

Then, the silicon oxide film 109 on the field plate electrode 30 is selectively removed. Subsequently, a conductive film (not shown) is deposited on the entire surface of the wafer. Then, the conductive film is etched back, leaving a gate electrode 50 inside the trench 107.

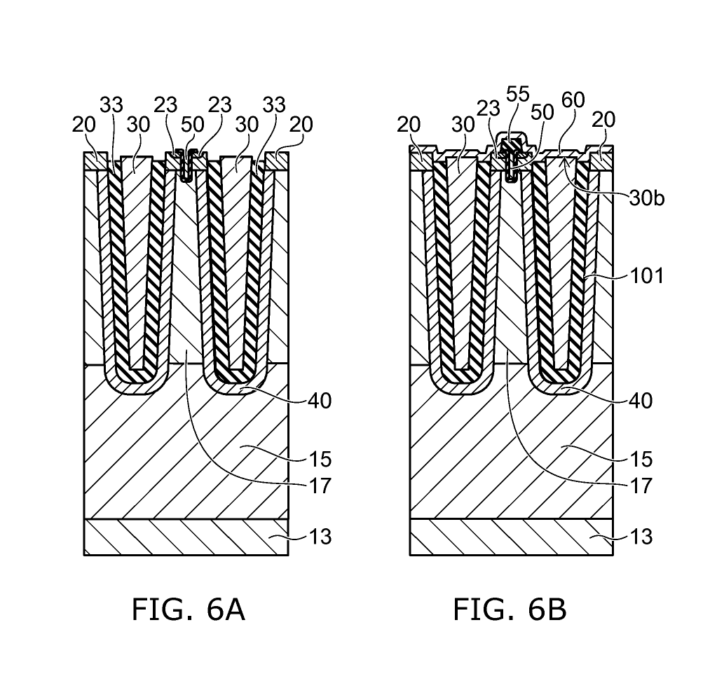

As shown in FIG. 6A, a base layer 20 is formed on the second layer 17. For example, the field plate insulating film 33 is etched back to expose the upper surface 17a of the second layer 17. Subsequently, the p-type impurities such as boron are ion-implanted into the exposed surface of the second layer 17 to form a base layer 20. For example, the p-type layer 40 in the upper part of the second layer 17 joins the base layer 20. Then, the base layer 20 and the p-type layer 40 are connected to each other.

Furthermore, a source layer 23 is selectively formed on the base layer 20 on the gate electrode 50 side. For example, n-type impurities such as arsenic (As) are selectively ion-implanted into the base layer 20 on the gate electrode 50 side.

Next, as shown in FIG. 6B, an interlayer insulating film 55 is selectively formed on the gate electrode 50. A source electrode 60 is formed to cover the base layer 20, the source layer 23, the field plate electrode 30, and the interlayer insulating film 55. The source electrode 60 is electrically connected to the base layer 20, the source layer 23, and is in contact with the field plate electrode 30.

In this embodiment, the source electrode 60 is formed in direct contact with the field plate electrode 30 exposed in the opening of the trench 101, and reduce the resistance of the field plate electrode 30. Thereby, it becomes possible to suppress the self turn-on, for example.

In the trench gate structure that includes a field plate electrode and a gate electrode provided in the same trench, a connecting portion is necessary for electrically connecting the source electrode to the field plate electrode. In contrast, in this embodiment, the source electrode 60 is in direct contact with the field plate electrode 30. Thus, there is no need to provide such a connecting portion. This enables the chip area to be effectively used as the active area. For example, it becomes possible to reduce the on-resistance by widening the active area. In another aspect, it also contributes to the downsizing of the semiconductor device 1.

Furthermore, the p-type layer 40 is interposed between the field plate insulating film 33 and the drift layer 10 in this embodiment. Thus, the source-drain capacitance C_{OSS} may be reduced by the p-type layer 40. The field plate electrode 30 and the gate electrode 50 are provided in the separate trenches respectively. The gate-source capacitance C_{gs} may also be reduced, and thereby, it becomes possible to improve the switching rate of the semiconductor device 1.

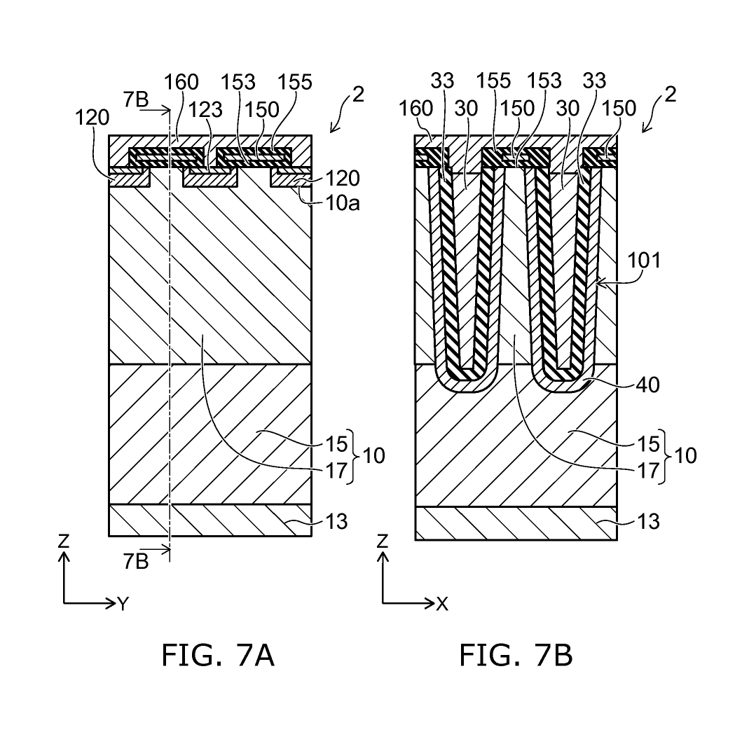

FIGS. 7A and 7B are schematic cross-sectional views illustrating a semiconductor device 2 according to a variation of the embodiment. FIG. 7A is a cross-sectional view taken along the Y-Z plane of the semiconductor device 2. FIG. 7B is a cross-sectional view taken along line 7B-7B shown in FIG. 7A.

The semiconductor device 2 includes a drift layer 10 provided on a drain layer 13. The drift layer 10 includes a first layer 15 and a second layer 17. The semiconductor device 2 includes a planar gate structure provided on the second layer 17.

As shown in FIG. 7A, the semiconductor device 2 includes a base layer 120 selectively provided on the second layer 17, and a source layer 123 selectively provided on the base layer 120. The gate electrode 150 is provided on a part of the second layer 17, a part of the base layer 120, and a part of the source layer 123 via a gate insulating film 153.

As shown in FIG. 7B, the semiconductor device 2 includes field plate electrodes 30. The field plate electrodes 30 are arranged in the X-direction. The field plate electrode 30 extends in the Z-direction in the drift layer 10. The first end 30a thereof is located in the first layer 15.

The semiconductor device 2 includes a p-type layer 40 and a field plate insulating film 33. The p-type layer 40 is provided between the drift layer 10 and each of the field plate electrodes 30. The field plate insulating film 33 is provided between each of the field plate electrodes 30 and the p-type layer 40.

For example, the field plate electrode 30 is provided via the field plate insulating film 33 in a trench 101 extending through the base layer 120 to the drift layer 10. The p-type layer 40 is provided along the field plate insulating film 33.

As shown in FIG. 7B, the gate electrode 150 is provided between the trenches 101 adjacent in the X-direction. The p-type layer 40 is provided to extend in the Y-direction, and connected to the base layers 120 selectively arranged in the Y direction.

In this embodiment, the p-type layer 40 is interposed between the field plate insulating film 33 and the drift layer 10. This may reduce the voltage applied to the field plate insulating film 33. Thus, the field plate insulating film 33 may be provided with a thinner thickness compared with the case without the p-type layer 40. Furthermore, the source-drain capacitance C_{OSS} can be reduced by interposing the p-type layer 40 between the field plate insulating film 33 and the drift layer 10. The field plate electrode 30 is placed in the trench 101. The gate electrode 150 is provided on the drift layer 10 between the adjacent trenches 101. The gate-source capacitance C_{gs} is reduced, and thus, it becomes possible to improve a switching rate of the semiconductor device 2.

In the embodiments described above, although the field plate electrodes 33 are shown to be separated from each other in the cross-sectional view, the field electrodes 33 may be connected to each other in a top-view thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor layer of a first conductivity type;
a first electrode over the first semiconductor layer;
a second electrode extending in a first direction from the first electrode to the first semiconductor layer, the second electrode having a first end in the first semiconductor layer and a second end in contact with the first electrode;
a third electrode extending in the first direction, the third electrode having a first end in the first semiconductor layer and a second end in contact with the first electrode;
a second semiconductor layer of a second conductivity type on the first semiconductor layer between the second electrode and the third electrode;
third semiconductor layers of the second conductivity type between the first semiconductor layer and the second electrode and between the first semiconductor layer and the third electrode;
first insulating films between one of the third semiconductor layers and the second electrode and between the other of the third semiconductor layers and the third electrode;
a fourth semiconductor layer of the first conductivity type on the second semiconductor layer, the fourth semiconductor layer being electrically connected to the first electrode; and
a fourth electrode extending through the fourth semiconductor layer and the second semiconductor layer to the first semiconductor layer via a second insulating film.

2. The device according to claim 1, wherein
the first semiconductor layer includes a first layer and a second layer, the second layer being provided between the first layer and the second semiconductor layer and having a higher impurity concentration of the first conductivity type than the first layer, and
the first end of the first electrode is located in the first layer.

3. The device according to claim 1, wherein
the first semiconductor layer has a first surface on a side opposite to the second semiconductor layer;
the fourth electrode has a first end in the first semiconductor layer and a second end opposite to the first end; and
a distance between the first surface and the first end of the fourth electrode is longer than a distance between the first surface and each of the first ends of the second electrode and the third electrode.

4. The device according to claim 3, wherein
the first semiconductor layer includes a first layer and a second layer, the second layer being provided on the first layer and having a higher impurity concentration of the first conductivity type than the first layer, and
each of the first ends of the second electrode and the third electrode is located in the first layer, and the first end of the fourth electrode is located in the second layer.

5. The device according to claim 3, wherein a distance between the first surface and the second end of the fourth electrode is longer than a distance between the first surface and the fourth semiconductor layer.

6. The device according to claim 1, wherein
the fourth semiconductor layer has a surface that is in contact with the first electrode.

7. The device according to claim 1, wherein the third semiconductor layers extend along the first insulating films, and the third semiconductor layers are connected to the second semiconductor layer.

8. The device according to claim 1, wherein
the second semiconductor layer is interposed between each of the third semiconductor layer and the first electrode, and
each of the third semiconductor layers is not in contact with the first electrode.

9. The device according to claim 1, further comprising:
a third insulating film provided between the first electrode and the fourth electrode.

10. The device according to claim 1, wherein a total amount of impurities of the second conductivity type contained in the third semiconductor layers is equal to a total amount of impurities of the first conductivity type contained in the first semiconductor layer and the third semiconductor layers.

11. The device according to claim 1, wherein the first electrode is made of metal, and the second electrode and the third electrode are made of polycrystalline silicon.

12. A semiconductor device comprising:
a first semiconductor layer of a first conductivity type having a first surface and a second surface on a side opposite to the first surface;
a first electrode over the second surface of the first semiconductor layer;
a second electrode extending in the semiconductor layer in a first direction from the second surface to the first surface;
a third electrode extending in the semiconductor layer in the first direction;
a second semiconductor layer of a second conductivity type selectively provided on the first semiconductor layer between the second electrode and the third electrode;
third semiconductor layers of the second conductivity type between the first semiconductor layer and the second electrode and between the first semiconductor layer and the third electrode;
first insulating films between one of the third semiconductor layers and the second electrode and between the other of the third semiconductor layers and the third electrode;
a fourth semiconductor layer of the first conductivity type selectively provided on the second semiconductor layer, the fourth semiconductor layer being electrically connected to the first electrode; and
a fourth electrode provided via a second insulating film on exposed parts in the second surface of the first semiconductor layer, the second semiconductor layer, and the fourth semiconductor layer.

13. The device according to claim 12, wherein
the first semiconductor layer includes a first layer and a second layer, the second layer being provided on the first layer and having a higher impurity concentration of the first conductivity type than the first layer, and
a distance between the first surface and each end of the second electrode and the third electrode on the first surface side is shorter than a distance between the second layer and the first surface.

14. The device according to claim 12, wherein the third semiconductor layers extend along the first insulating films, and the third semiconductor layers are connected to the second semiconductor layer.
